(19) United States
(12) Patent Application Publication
(10) Pub. No.: US 2024/0192925 A1
(43) Pub. Date: Jun. 13, 2024

(54) MEMORY CORE AND SEMICONDUCTOR APPARATUS WITH TRANSPOSED MATRIX CALCULATION FUNCTION INCLUDING THE SAME

(71) Applicant: SK hynix Inc., Icheon-si Gyeonggi-do (KR)

(72) Inventors: Gi Moon HONG, Icheon-si Gyeonggi-do (KR); Dae Han KWON, Icheon-si Gyeonggi-do (KR)

(73) Assignee: SK hynix Inc., Icheon-si Gyeonggi-do (KR)

(21) Appl. No.: 18/325,836

(22) Filed: May 30, 2023

(30) Foreign Application Priority Data
Dec. 9, 2022 (KR) 10-2022-0171389

(51) Int. Cl. G06F 7/78; G11C 11/408; G11C 11/4091; G11C 11/4096

(52) U.S. Cl. CPC G06F 7/78; G11C 11/4085; G11C 11/4091; G11C 11/4096

(57) ABSTRACT

A memory core includes a first signal line; a second signal line; a first transistor coupled between the second signal line and a data storage element; a second transistor coupled between the first signal line and the data storage element; and a switching circuit configured to, in response to a mode selection signal, switch an operation of the memory core between a first mode and a second mode, the first mode controlling the first transistor according to a level of the first signal line and turning off the second transistor and a second mode controlling the second transistor according to a level of the second signal line and turning off the first transistor.

### CROSS-REFERENCES TO RELATED APPLICATION

The present application claims priority under 35 U.S.C. § 119(a) to Korean Patent Application Number 10-2022-0171389, filed on Dec. 9, 2022, in the Korean Intellectual Property Office, which is incorporated herein by reference in its entirety.

### BACKGROUND

### 1. Technical Field

various embodiments may generally relate to a semiconductor circuit, and more particularly, to a memory core and a semiconductor apparatus with a transposed matrix calculation function including the same.

### 2. Related Art

Data processing apparatuses, for example, central processing units (CPUs), graphic processing units (GPUs), and the like may support various application programs and have to perform a data calculation operation for each program.

Since data to be processed for 2-dimensional (2D) digital filtering or 2D fast Fourier transformation (2D-FFT), and the like, which are a data calculation operation, are massive, transpose of a 2D matrix is inevitably necessary. Further, in synthetic aperture radars (SARs) or unmanned aerial vehicles (UAVs), which is technology that mathematically reconstructs and visualizes radar information observed over a wide area through aircrafts or satellites, data to be processed through 2D digital filters are massive and real-time processing is required. Accordingly, it is essential to transpose a data matrix, and the performance of the transposed matrix calculation algorithm has a great influence on the performance of systems.

To perform the transposed matrix calculation, semiconductor apparatuses, for example, semiconductor memory apparatuses configured to store data in calculation processes are essential, and the semiconductor memory apparatuses configured to quickly perform the accurate transposed matrix calculation may be essential.

### SUMMARY

In an embodiment of the present disclosure, a memory core may include: a first signal line; a second signal line; a first transistor coupled between the second signal line and a data storage element; a second transistor coupled between the first signal line and the data storage element; and a switching circuit configured to, in response to a mode selection signal, switch an operation of the memory core between a first mode and a second mode controlling the first transistor according to a level of the first signal line and turning off the second transistor and a second mode controlling the second transistor according to a level of the second signal line and turning off the first transistor.

In an embodiment of the present disclosure, a semiconductor apparatus may include: a memory core including a plurality of unit memory regions having a plurality of unit cells coupled between a plurality of first signal lines and a plurality of second signal lines, wherein each of the plurality of unit cells is configured to perform data input/output (I/O) according to a level of a corresponding first signal line through a corresponding second signal line when an operation mode of the memory core is set to a first mode and configured to perform data I/O according to a level of the corresponding second signal line through the corresponding first signal line when the operation mode of the memory core is set to a second mode; a data I/O circuit coupled between the memory core and an I/O pad circuit; and a control circuit, in response to a transposed matrix calculation command, configured to perform a transposed matrix calculation by controlling mode switching between the first mode and the second mode and a data exchange between the plurality of unit memory regions and the data I/O circuit.

In an embodiment of the present disclosure, a memory core may include: a word line and a bit line arranged in a matrix form; a first transistor coupled between the bit line and a data storage element; a second transistor coupled between the word line and the data storage element; and a switching circuit configured to: control the first transistor according to a level of the word line and turn off the second transistor when a mode selection signal has a level defining an operation mode of the memory core as a first mode; and control the second transistor according to a level of the bit line and turn off the first transistor when the mode selection signal has a level defining the operation mode of the memory core as a second mode.

These and other features, aspects, and embodiments are described in more detail below.

### BRIEF DESCRIPTION OF THE DRAWINGS

The above and other aspects, features and advantages of the subject matter of the present disclosure will be more clearly understood from the following detailed description taken in conjunction with the accompanying drawings, in which:

FIG. 1 is a diagram illustrating a configuration of a semiconductor apparatus according to an embodiment of the present disclosure;

FIG. 2 is a diagram illustrating a configuration of a memory core of FIG. 1;

FIG. 3 is a diagram illustrating a configuration of a data I/O circuit of FIG. 1;

FIG. 4 is a diagram illustrating a transposed matrix calculation method according to an embodiment of the present disclosure;

FIG. 5 is a diagram illustrating a configuration of a semiconductor apparatus according to another embodiment of the present disclosure;

FIG. 6 is a diagram illustrating a configuration of a memory core of FIG. 5;

FIG. 7 is a diagram explaining an operation of the memory core of FIG. 6 in a first mode according to another embodiment of the present disclosure;

FIG. 8 is a diagram explaining an operation of the memory core of FIG. 6 in a second mode according to another embodiment of the present disclosure; and

FIG. 9 is a diagram illustrating a transposed matrix calculation method according to another embodiment of the present disclosure.

### DETAILED DESCRIPTION

Various embodiments of the present teachings are described in detail with reference to the accompanying drawings. The drawings are schematic illustrations of various embodiments (and intermediate structures). As such, variations from the configurations and shapes of the illustrations as a result, for example, of manufacturing techniques and/or tolerances, are to be expected. Thus, the described embodiments should not be construed as being limited to the particular configurations and shapes illustrated herein but may include deviations in configurations and shapes which do not depart from the spirit and scope of the present teachings as defined in the appended claims.

The present teachings are described herein with reference to cross-section and/or plan illustrations of idealized embodiments of the present teachings. However, embodiments of the present teachings should not be construed as limiting the present teachings. Although a few embodiments of the present teachings are shown and described, it will be appreciated by those of ordinary skill in the art that changes may be made in these embodiments without departing from the principles and spirit of the present teachings.

Embodiments are provided to a memory core having a structure that facilitates a quickly transposed matrix calculation accurately and a semiconductor apparatus including the same.

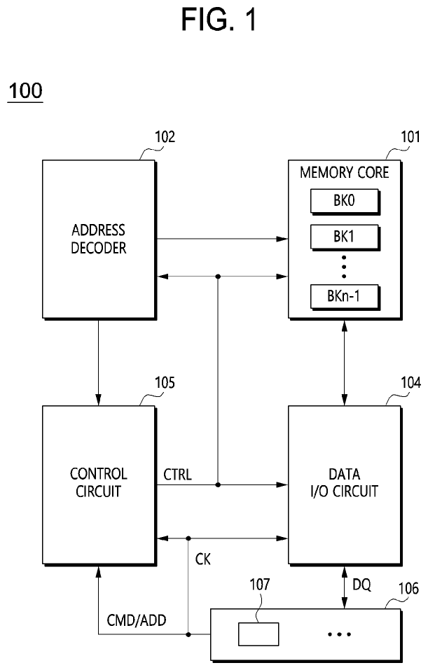

FIG. 1 is a diagram illustrating a configuration of a semiconductor apparatus 100 according to an embodiment of the present disclosure.

Referring to FIG. 1, the semiconductor apparatus 100 according to an embodiment may include a memory core 101, an address decoder 102, a data input/output (I/O) circuit 104, a control circuit 105, and an I/O pad circuit 106.

The memory core 101 may include a plurality of unit cells, and each of the plurality of unit cells may be configured of at least one of a volatile memory and a nonvolatile memory. The volatile memory may include a static random access memory (SRAM), a dynamic RAM (DRAM), a synchronous DRAM (SDRAM), and the like, and the nonvolatile memory may include a read only memory (ROM), a programmable ROM (PROM), an electrically erase and programmable ROM (EEPROM), an electrically programmable ROM (EPROM), a flash memory, a phase-change RAM (PRAM), a magnetic RAM (MRAM), a resistive RAM (RRAM), a ferroelectric RAM (FRAM), and the like. The plurality of unit cells in the memory core 101 may be divided into a plurality of unit memory regions, for example, a plurality of memory banks BK0 to BKn−1 (hereinafter, referred to as banks).

The address decoder 102 may be coupled to the control circuit 105 and the memory core 101. The address decoder 102 may decode an address signal provided from the control circuit 105 and may access the memory core 101 in response to a decoding result.

The data I/O circuit 104 may be coupled to the memory core 101. The data I/O circuit 104 may exchange data with an external system or the memory core 101.

The control circuit 105 may be coupled to the memory core 101, the address decoder 102, and the data I/O circuit 104. The control circuit 105 may receive a command CMD, an address ADD, a clock signal CK, and the like, for example, from the external system through the I/O pad circuit 106. The control circuit 105 may provide the address decoded through the address decoder 102 to the data I/O circuit 104. The control circuit 105 may control an overall operation, for example, a test operation and a normal operation of the semiconductor apparatus 100. The normal operation may include a read operation, a write operation, and an address processing operation. The control circuit 105 may control a transposed matrix calculation operation by controlling data exchange between the plurality of banks BK0 to BKn−1 and the data I/O circuit 104 in response to a transposed matrix calculation command. The control circuit 105 may include an algorithm for performing the transposed matrix calculation in a software or/and hardware form. The control circuit 105 may generate a plurality of control signals CTRL for controlling the test operation, the normal operation, and the transposed matrix calculation operation of the semiconductor apparatus 100.

The I/O pad circuit 106 may include a plurality of pads 107 configured to receive the command CMD, the address ADD, and the clock signal CK and to input and output data DQ.

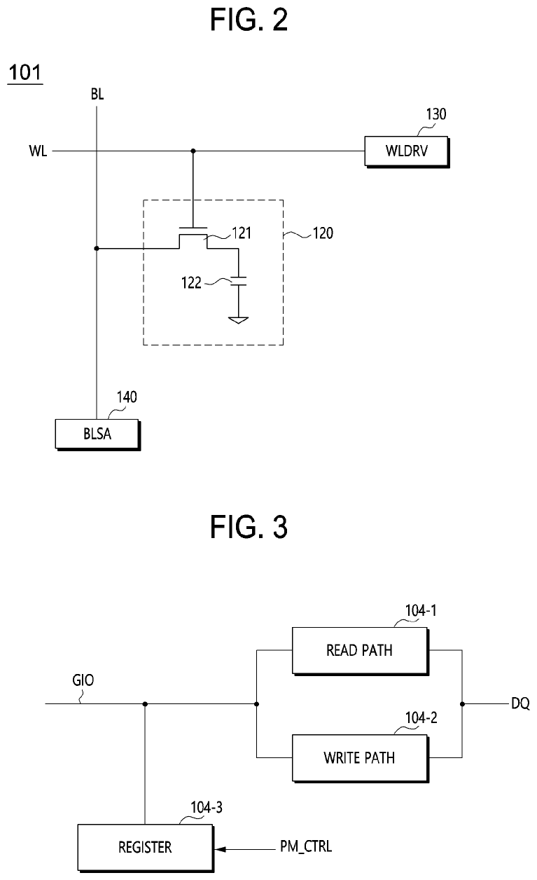

FIG. 2 is a diagram illustrating a configuration of the memory core 101 of FIG. 1.

The memory core 101 may include a plurality of word lines, a plurality of bit lines arranged in a matrix form, and a plurality of unit cells coupled to the plurality of word lines and the plurality of bit lines. The plurality of unit cells may be divided into the plurality of banks BK0 to BKn−1 and may be controlled in bank units. As described above, each of the plurality of unit cells may be configured of various types of memory cells, such as a DRAM, a SRAM, a NAND flash memory, and the like. For example, a configuration of a unit cell configured of a DRAM cell will be described with reference to FIG. 2.

Referring to FIG. 2, a unit cell 120 may include a transistor 121 and a data storage element 122, for example, a capacitor 122.

A drain terminal of the transistor 121 may be coupled to a bit line BL, a source terminal thereof may be coupled to one terminal of the capacitor 122, and a gate terminal thereof may be coupled to a word line WL. The other terminal of the capacitor 122 may be coupled to a ground terminal.

A word line driver (WLDRV) 130 configured to drive the word line WL may be coupled to the word line WL. A bit line sense amplifier (BLSA) 140 configured to sense and amplify data stored in the capacitor 122 may be coupled to the bit line BL.

FIG. 3 is a diagram illustrating a configuration of the data I/O circuit 104 of FIG. 1.

Referring to FIG. 3, the data I/O circuit 104 may include a read path 104-1, a write path 104-2, and a register 104-3.

The read path 104-1 may be configured to transmit data transferred through a global I/O line GIO to the I/O pad circuit 106. In a read operation of the semiconductor apparatus 100, parallel data may be transmitted through the global I/O line GIO. The read path 104-1 may include a pipeline register configured to arrange the parallel data transferred through the global I/O line GIO to be matched at a predetermined timing.

The write path 104-2 may be configured to transmit data input through the I/O pad circuit 106 to the global I/O line GIO.

In a transposed matrix calculation operation, the register 104-3 may be coupled to the global I/O line GIO and may be configured to perform, in response to a transposed matrix calculation control signal PM_CTRL, an operation that stores data of the global I/O line GIO and an operation that transmits data stored therein to the global I/O line GIO. The transposed matrix calculation control signal PM_CTRL may be included in the plurality of control signals CTRL generated in the control circuit 105.

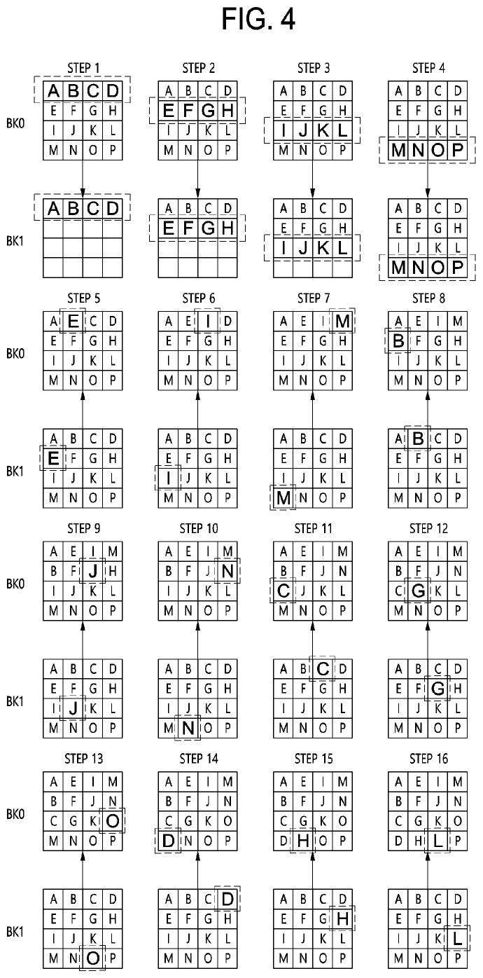

FIG. 4 is a diagram explaining a transposed matrix calculation method according to an embodiment of the present disclosure.

The transposed matrix calculation method according to an embodiment of the present disclosure will be described with reference to FIGS. 1 to 4.

The transposed matrix calculation may be an operation that switches row and column indices in a matrix of data. For example, it is assumed that data A to P of 4*4 matrix are stored in a first bank BK0 as shown in first step STEP 1 of FIG. 4. A final target of the transposed matrix calculation may transpose the data A to P of 4*4 matrix, which are stored in the first bank BK0, to the data A to P of 4*4 matrix as in sixteenth step STEP 16.

It is illustrated in the embodiment that only a command for performing the transposed matrix calculation is provided from the outside of the semiconductor apparatus 100, and the semiconductor apparatus 100 is configured to perform the transposed matrix calculation on its own without external control.

The control circuit 105 may control a read operation to be performed as in first step STEP 1 and may control data A to D in a first row, among the data A to P of 4*4 matrix, which are stored in the first bank BK0, to be output to the global I/O line GIO when the transposed matrix calculation command is input, for example, when the command CMD input from the outside defines the transposed matrix calculation. After the read operation, the control circuit 105 may control the data A to D, which are output from the first bank BK0 through the global I/O line GIO, to be stored in the register 104-3. Next, the control circuit 105 may control a write operation to be performed and may control the data A to D stored in the register 104-3 to be stored in a first row of a second bank BK1 through the global I/O line GIO. Since the transposed matrix calculation is not a data exchange operation with an external system outside the semiconductor apparatus 100, the control circuit 105 may allow the read path 104-1 and the write path 104-2 to be maintained in an inactivated state while the transposed matrix calculation is being performed. The control circuit 105 may control a data I/O operation of the register 104-3 by adjusting a level of the transposed matrix calculation control signal PM_CTRL.

As in the transposed matrix calculation operation as in first step STEP1, the control circuit 105 may perform a transposed matrix calculation as in second step STEP 2 to fourth step STEP 4 and may copy the data A to P stored in the first bank BK0 to the second bank BK1.

The control circuit 105 may perform a transposed matrix calculation as in fifth step STEP 5 to seventh step STEP 7 and may store data E, I, and M in a first column, among the data A to P of 4*4 matrix, which are stored in the second bank BK1, in the first row of the first bank BK0. The data A, E, I, and M stored in the first column of the first bank BK0 may be rearranged in the first row of the first bank BK0 through the transposed matrix calculation as in fifth step STEP 5 to seventh step STEP 7.

The control circuit 105 may perform transposed matrix calculation through the remaining steps, for example, eighth step STEP 8 to sixteenth step STEP 16, in a similar manner as fifth step STEP 5 to seventh step STEP 7, and may complete the transposed matrix calculation that switches data in the rows and columns of all the data A to P stored in the first bank BK0. The data that are a result indicating that the transposed matrix calculation is completed, stored in the first bank BK0, may be provided to an external system outside the semiconductor apparatus 100 through the I/O pad circuit 106 via the read path 104-1, according to a request from the outside of the semiconductor apparatus 100.

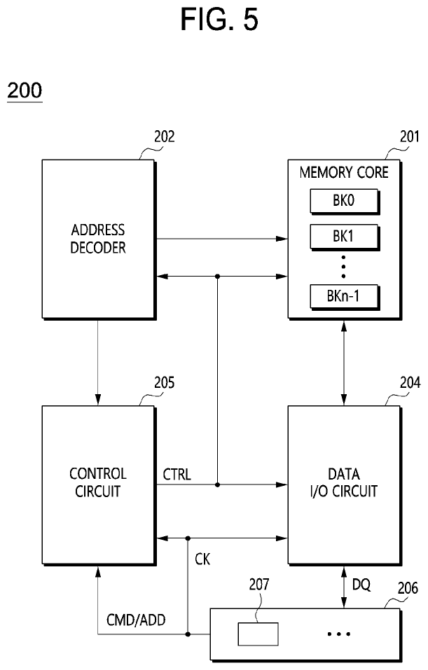

FIG. 5 is a diagram illustrating a configuration of a semiconductor apparatus 200 according to another embodiment of the present disclosure.

Referring to FIG. 5, the semiconductor apparatus 200 according to another embodiment may include a memory core 201, an address decoder 202, a data I/O circuit 204, a control circuit 205, and an I/O pad circuit 206.

The memory core 201 may include a plurality of unit memory regions having a plurality of unit cells, for example, a plurality of memory banks BK0 to BKn−1. A unit cell of the memory core 201 may be configured to perform data I/O through a second signal line according to a level of a first signal line when an operation mode of the memory core 201 is set to a first mode and may be configured to perform data I/O through the first signal line according to a level of the second signal line when the operation mode of the memory core 201 is set to a second mode.

The address decoder 202 may have the same configuration as the address decoder 102 of FIG. 1.

The data I/O circuit 204 may have the same configuration as the data I/O circuit 104 of FIG. 1.

The control circuit 205 may be coupled to the memory core 201, the address decoder 202, and the data I/O circuit 204. The control circuit 205 may receive a command CMD, an address ADD, a clock signal CK, and the like through the I/O pad circuit 206 from an external system. The control circuit 205 may provide the address, decoded through the address decoder 202, to the data I/O circuit 204. The control circuit 205 may control an overall operation of the semiconductor apparatus 200, for example, a test operation and a normal operation. The normal operation of the semiconductor apparatus 200 may include a read operation, a write operation, and an address processing operation. In response to a transposed matrix calculation command, the control circuit 205 may control a transposed matrix calculation operation by controlling an operation mode switching of the unit cell of the memory core 201 between the first mode and the second mode and by controlling a data exchange between the plurality of banks BK0 to BKn−1 and the data I/O circuit 204. The control circuit 205 may include an algorithm for performing the transposed matrix calculation in a software form and/or a hardware form. The control circuit 205 may generate a plurality of control signals CTRL for controlling the test operation, the normal operation, and the transposed matrix calculation operation of the semiconductor apparatus 200.

The I/O pad circuit 206 may have the same configuration as the I/O pad circuit 106 of FIG. 1.

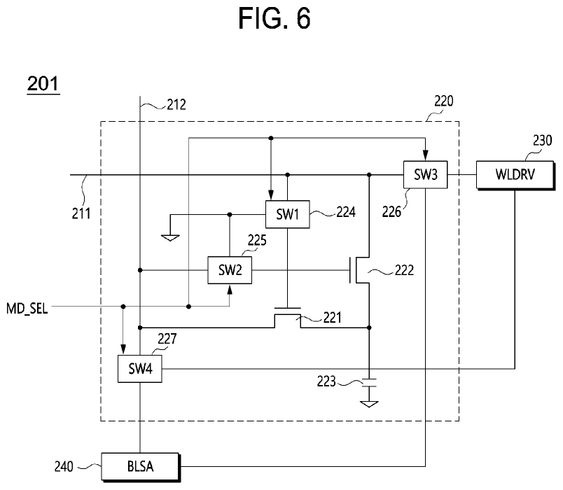

FIG. 6 is a diagram illustrating a configuration of the memory core 201 of FIG. 5.

The memory core 201 may include the plurality of unit cells. The plurality of unit cells may be configured of various types of memory cells, such as a DRAM cell, a SRAM cell, a NAND flash cell, and the like. An example that the unit cell is configured of a DRAM cell will be described with reference to FIG. 6.

Referring to FIG. 6, the memory core 201 may include a first signal line 211, a second signal line 212, and a unit cell 220. The unit cell 220 may include a plurality of transistors 221 and 222 and a storage device 223, for example, a capacitor 223. The plurality of transistors 221 and 222 may include a first transistor 221 that operates as a cell transistor in the first mode and a second transistor 222 that operates as a cell transistor in a second mode. The first mode may be one mode of the read operation and the write operation of the memory core 201, for example, the unit cell 220, and the second mode may be the other mode of the read operation and the write operation of the memory core 201, for example, the unit cell 220.

Although it is illustrated in FIG. 6 that the memory core 201 includes the single memory cell 220 being coupled to a single first signal line 211 and a single second signal line 212, the disclosure is not limited thereto. For example, a plurality of first signal lines 211 and a plurality of second signal lines 212 may be arranged in a matrix form, and the plurality of unit cells 220 may be coupled to the first signal lines 211 and the second signal lines 212. The first signal line 211 and the second signal line 212 may correspond to the word line WL and the bit line BL of the unit cell 120, illustrated in FIG. 2. In the first mode, the first signal line 211 may operate as the word line WL, and the second signal line 212 may operate as the bit line BL. In the second mode, the first signal line 211 may operate as the bit line BL, and the second signal line 212 may operate as the word line WL.

A source terminal of the first transistor 221 may be coupled to a first terminal of the data storage element 223, for example, the capacitor 223, and a drain terminal thereof may be coupled to the second signal line 212. A second terminal of the capacitor 223 may be coupled to a ground terminal.

A source terminal of the second transistor 222 may be coupled to the first terminal of the capacitor 223, and a drain terminal thereof may be coupled to the first signal line 211.

The unit cell 220 may further include a switching circuit configured to switch the operation mode of the unit cell 220 to the first mode or the second mode in response to a mode selection signal MD_SEL. In the first mode, the first transistor 221 may be controlled to operate as a cell transistor according to a level of the first signal line 211 in a turn-off state of the second transistor 222. In the second mode, the second transistor 222 may be controlled to operate as a cell transistor according to a level of the second signal line 212 in a turn-off state of the first transistor 221. The mode selection signal MD_SEL may be included in the plurality of control signals CTRL generated in the control circuit 205.

The switching circuit may include a first switch 224, a second switch 225, a third switch 226, and a fourth switch 227. The first switch 224 may be configured to, in response to the mode selection signal MD_SEL, couple the first signal line 211 to a gate terminal of the first transistor 221 in the first mode and couple the ground terminal to the gate terminal of the first transistor 221 in the second mode. The second switch 225 may be configured to, in response to the mode selection signal MD_SEL, couple the second signal line 212 to a gate terminal of the second transistor 222 in the second mode and couple the ground terminal to the gate terminal of the second transistor 222 in the first mode. For example, the first and second switches 224 and 225 may decouple the gate terminals of the first and second transistors 221 and 222 from the first and second signal lines 211 and 212 in the second and first modes, respectively. In this example, the first and second switches 224 and 225 may couple the gate terminals of the first and second transistors 221 and 222 to the ground terminal to be turned off in the second and first modes. In response to the mode selection signal MD_SEL, the third switch 226 may be configured to couple the first signal line 211 to a word line driver (WLDRV) 230 in the first mode and may be configured to couple the first signal line 211 to a bit line sense amplifier (BLSA) 240 in the second mode. In response to the mode selection signal MD_SEL, the fourth switch 227 may be configured to couple the second signal line 212 to the bit line sense amplifier 240 in the first mode and may be configured to couple the second signal line 212 to the word line driver 230 in the second mode.

A first terminal of the first switch 224 may be coupled to the gate terminal of the first transistor 221, a second terminal thereof may be coupled to the first signal line 211, and a third terminal thereof may be coupled to the ground terminal. When the mode selection signal MD_SEL has a level defining the first mode, for example, a low level, the first switch 224 may couple the gate terminal of the first transistor 221 to the first signal line 211 so that the first transistor may operate as a cell transistor. When the mode selection signal MD_SEL has a level defining the second mode, for example, a high level, the first switch 224 may couple the gate terminal of the first transistor 221 to the ground terminal so that the first transistor 221 may turn off.

A first terminal of the second switch 225 may be coupled to the gate terminal of the second transistor 222, a second terminal thereof may be coupled to the second signal line 212, and a third terminal thereof may be coupled to the ground terminal. When the mode selection signal MD_SEL has the high level, the second switch 225 may couple the gate terminal of the second transistor 222 to the second signal line 212 so that the second transistor 222 may operate as a cell transistor. When the mode selection signal MD_SEL has the low level, the second switch 225 may couple the gate terminal of the second transistor 222 to the ground terminal so that the second transistor 222 may turn off.

A first terminal of the third switch 226 may be coupled to the first signal line, a second terminal thereof may be coupled to the word line driver (WLDRV) 230 configured to drive the word line WL, and a third terminal thereof may be coupled to the bit line sense amplifier (BLSA) 240 configured to sense and amplify data stored in the capacitor 223. The third switch 226 may couple the first signal line 211 to the word line driver 230 when the mode selection signal MD_SEL has the low level. The third switch 226 may couple the first signal line 211 to the bit line sense amplifier 240 when the mode selection signal MD_SEL has the high level.

A first terminal of the fourth switch 227 may be coupled to the second signal line 212, a second terminal thereof may be coupled to the bit line sense amplifier 240, and a third terminal thereof may be coupled to the word line driver 230. The fourth switch 227 may couple the second signal line 212 to the bit line sense amplifier 240 when the mode selection signal MD_SEL has the low level. The fourth switch 227 may couple the second signal line 212 to the word line driver 230 when the mode selection signal MD_SEL has the high level.

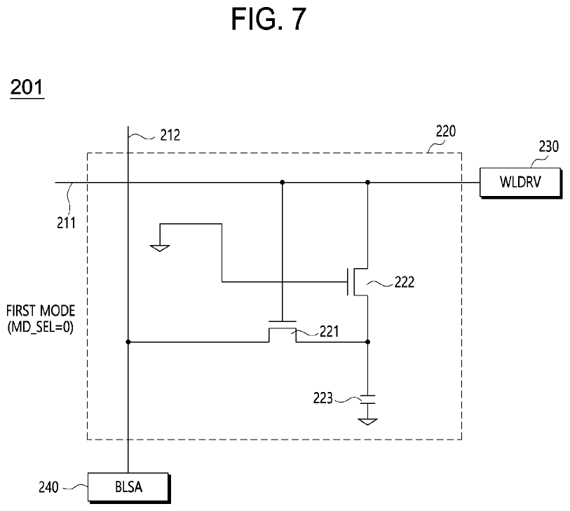

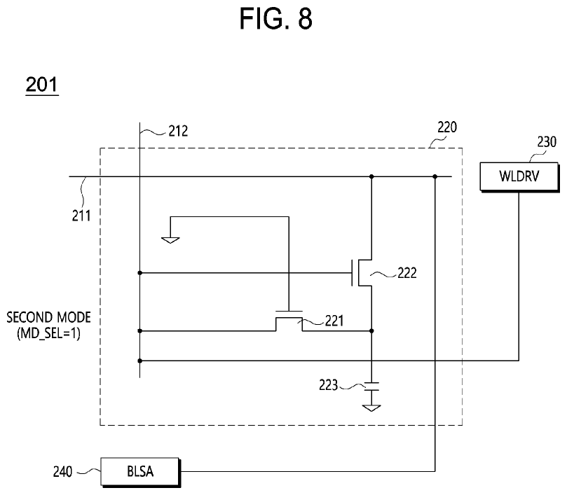

FIG. 7 is a diagram explaining an operation of the memory core 201 of FIG. 6 in the first mode according to another embodiment of the present disclosure, and FIG. 8 is a diagram explaining an operation of the memory core 201 of FIG. 6 in the second mode according to another embodiment of the present disclosure.

As described above, the operation mode of the memory core 201 may be switched between the first mode and the second mode according to the mode selection signal MD_SEL. Hereinafter, the operations of the memory core 201 in the first mode and the second mode will be described with reference to FIGS. 7 and 8.

Referring to FIG. 7, when the mode selection signal MD_SEL has the level defining the first mode, for example, the low level, the memory core 201 may operate in the first mode.

In the first mode, the second transistor 222 may turn off, and the first transistor 221 may be controlled according to the level of the first signal line 211. The first signal line 211 may be coupled to the word line driver 230 through the third switch 226, and the second signal line 212 may be coupled to the bit line sense amplifier 240 through the fourth switch 227.

As the first signal line 211 is driven to the high level through the word line driver 230, the data stored in the capacitor 223 may be output to the bit line sense amplifier 240 through the second signal line 212.

In the first mode, the first signal line 211 may operate as the word line, and the second signal line 212 may operate as the bit line. Accordingly, data stored in unit cells arranged in rows, among unit cells of a memory bank, may be output.

Referring to FIG. 8, when the mode selection signal MD_SEL has the level defining the second mode, for example, the high level, the memory core 201 may operate in the second mode.

In the second mode, the first transistor 221 may turn off, and the second transistor 222 may be controlled according to the level of the second signal line 212. The first signal line 211 may be coupled to the bit line sense amplifier 240 through the third switch 226, and the second signal line 212 may be coupled to the word line driver 230 through the fourth switch 227.

As the second signal line 212 is driven to the high level through the word line driver 230, data stored in the capacitor 223 may be output to the bit line sense amplifier 240 through the first signal line 211.

In the second mode, the first signal line 211 that operates as the word line in the first mode may operate as the bit line, and the second signal line 212 that operates as the bit line in the first mode may operate as the word line. Accordingly, data stored in unit cells arranged in columns among unit cells of a memory bank may be output.

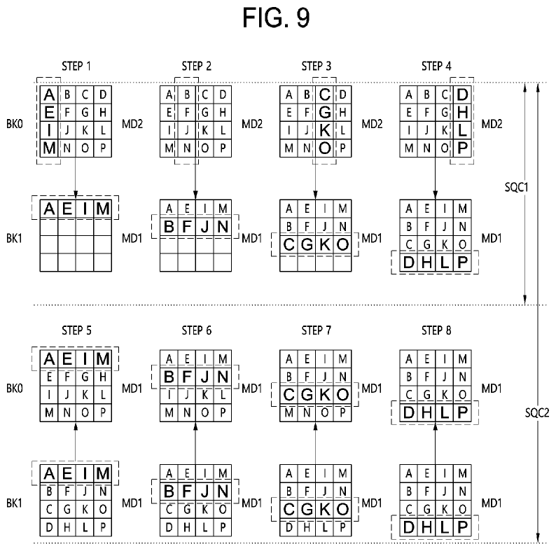

FIG. 9 is a diagram exampling a transposed matrix calculation operation according to another embodiment of the present disclosure.

The transposed matrix calculation method according to another embodiment of the present disclosure will be described with reference to FIGS. 5 to 9.

It is exemplary that the transposed matrix calculation on data A to P of 4*4 matrix in a first bank BK0 is performed. A final target of the transposed matrix calculation may transpose data in rows and columns of the data A to P of 4*4 matrix, which are stored in the first bank BK0.

It is illustrated in another embodiment that only a command for performing the transposed matrix calculation is provided from the outside of the semiconductor apparatus 200, and the semiconductor apparatus 200 is configured to perform the transposed matrix calculation on its own without external control. The transposed matrix calculation according to another embodiment may be performed through one of two types of sequences. A first sequence SQC1 may be a method that stores a result transposed in columns and rows of the data A to P 4*4 matrix that are not in the original bank but in another bank, and a second sequence SQC2 may be a method that stores a result transposed in columns and rows of the data A to P 4*4 matrix in the original bank.

First, the first sequence SQC1 will be described.

When the transposed matrix calculation command is input, for example, when the command CMD input from the outside defines a transposed matrix calculation, the control circuit 205 may generate the mode selection signal MD_SEL having the level defining the second mode MD2 and may control the memory core 201 to operate as the second mode MD2. As the read operation is being performed in the second mode MD2, data A, E, I, and M of unit cells in a column of the first bank BK0 may be output to the global I/O line GIO as in first step STEP 1. After the read operation, the control circuit 205 may control the register 104-3 to store the data A, E, I, and M therein. Then, the control circuit 205 may generate the mode selection signal MD_SEL having the level defining the first mode MD1 and may switch the operation mode of the memory core 201 to the first mode MD1. As the write operation is being performed in the first mode, the data A, E, I, and M stored in the register 104-3 may be stored in unit cells in a row of the second bank BK1 through the global I/O line GIO. The transposed matrix calculation might not be a data exchange operation with the outside of the semiconductor apparatus 200, and thus, the control circuit 205 may maintain the read path 104-1 and the write path 104-2 to be in an inactivated state while the transposed matrix calculation is being performed. The control circuit 205 may control data I/O of the register 104-3 by adjusting a level of the transposed matrix calculation control signal PM_CTRL.

While the control circuit 205 switches the operation mode of the memory core 201 as in first step STPE1, the control circuit 205 may transpose data in the rows and columns of the data A to P of 4*4 matrix stored in the first bank BK0 by performing second step STEP 2 to fourth step STEP 4, store a transposed result in the second bank BK1, and complete the first sequence SQC1. The data that is a result of the transposed matrix calculation, stored in the second bank BK1, may be provided to an external system outside the semiconductor apparatus 200 through the I/O pad circuit 206 via the read path 104-1 according to a request from the outside of the semiconductor apparatus 200.

Next, the second sequence SQC2 will be described.

Although the transposed matrix calculation is completed only through four steps in the first sequence SQC1, the transposed matrix calculation result might not be stored in the original bank (for example, the first bank BK0), but in another bank (for example, the second bank BK1). The semiconductor apparatus 200 may know the bank in which the transposed matrix calculation result is stored, and thus, it is not difficult to provide the corresponding result according to an external request. In other words, a semiconductor system may be configured to perform the transposed matrix calculation in association with an external host outside the semiconductor apparatus 200. In this case, it is advantageous to store the corresponding result in a predetermined bank in terms of a system control. Accordingly, the semiconductor apparatus 200 according to another embodiment may support the second sequence SQC2.

The second sequence SQC2 may further include fifth step STEP 5 to eighth step STEP 8 for transmitting the data A to P of 4*4 matrix, which are stored in the second bank BK1 through first to fourth steps STEP1 to STEP 4, to the first bank BK0 as the original bank, in addition to first to fourth steps STEP 1 to STEP 4.

Since the operation mode of the memory core 201 is set to the first mode MD1 in first to fourth steps STEP 1 to STEP 4, the control circuit 205 may perform the read operation as in fifth step STEP and may control the data A, E, I, and M of the unit cells in the first row of the second bank BK1 to be output to the global I/O line GIO, without the operation mode switching. After the read operation, the control circuit 205 may control the register 104-3 to store the data A, E, I, and M. Next, the control circuit 205 may perform the write operation and may control the data A, E, I, and M stored in the register 104-3 to be stored in the unit cells in the first row of the first bank BK0 through the global I/O line GIO.

The control circuit 105 may perform sixth step STEP 6 to eighth step STEP 8 in a similar manner as fifth step STEP 5, copy the data A to P stored in the second bank BK1 to the first bank BK0, and complete the second sequence SQC2.

As described above, the semiconductor apparatus 200 according to another embodiment may be configured to support the first mode in which the memory core 201 can output data in the rows of a corresponding bank and the second mode in which the memory core 201 can output data in the columns of a corresponding bank, as shown in FIG. 6. While the control circuit 205 switches the operation mode of the memory core between the first mode and the second mode, the control circuit 205 may control the transposed matrix calculation, and thus, the control circuit 205 may complete the transposed matrix calculation only through four steps. The embodiment of the present disclosure described with reference to FIGS. 5 to 9 may complete the transposed matrix calculation quickly as compared with the case in which the transposed matrix calculation is performed through the sixteen steps described with reference to FIGS. 1 to 4.

The above described embodiments of the present invention are intended to illustrate and not to limit the present invention. Various alternatives and equivalents are possible. The invention is not limited by the embodiments described herein. Nor is the invention limited to any specific type of semiconductor device. Other additions, subtractions, or modifications are obvious in view of the present disclosure and are intended to fall within the scope of the appended claims.

What is claimed is:

1. A memory core comprising:
a first signal line;
a second signal line;
a first transistor coupled between the second signal line and a data storage element;
a second transistor coupled between the first signal line and the data storage element; and
a switching circuit configured to, in response to a mode selection signal, switch an operation of the memory core between a first mode and a second mode, the first mode controlling the first transistor according to a level of the first signal line and turning off the second transistor and the second mode controlling the second transistor according to a level of the second signal line and turning off the first transistor.

2. The memory core of claim 1, wherein, in the first mode, the first signal line operates as a word line, and the second signal line operates as a bit line.

3. The memory core of claim 2, wherein, in the second mode, the first signal line operates as the bit line, and the second signal line operates as the word line.

4. The memory core of claim 1, wherein the switching circuit includes:
a first switch including a first terminal that is coupled to a gate terminal of the first transistor, a second terminal that is coupled to the first signal line, and a third terminal that is coupled to a ground terminal; and
a second switch including a first terminal that is coupled to a gate terminal of the second transistor, a second terminal that is coupled to the second signal line, and a third terminal that is coupled to the ground terminal.

5. The memory core of claim 1, wherein the memory core further includes:
a word line driver; and
a bit line sense amplifier,
wherein, in the first mode, the switching circuit is configured to couple the first signal line to the word line driver and configured to couple the second signal line to the bit line sense amplifier.

6. The memory core of claim 5, wherein, in the second mode, the switching circuit is configured to couple the first signal line to the bit line sense amplifier and configured to couple the second signal line to the word line driver.

7. A semiconductor apparatus comprising:
a memory core including a plurality of unit memory regions having a plurality of unit cells coupled between a plurality of first signal lines and a plurality of second signal lines, wherein each of the plurality of unit cells is configured to perform data input/output (I/O) according to a level of a corresponding first signal line through a corresponding second signal line when an operation mode of the memory core is set to a first mode and configured to perform data I/O according to a level of the corresponding second signal line through the corresponding first signal line when the operation mode of the memory core is set to a second mode;
a data I/O circuit coupled between the memory core and an I/O pad circuit; and
a control circuit configured to, in response to a transposed matrix calculation command, perform a transposed matrix calculation by controlling mode switching between the first mode and the second mode and a data exchange between the plurality of unit memory regions and the data I/O circuit.

8. The semiconductor apparatus of claim 7, wherein, in the first mode, the first signal line operates as a word line and the second signal line operates as a bit line, and
wherein, in the second mode, the first signal line operates as the bit line and the second signal line operates as the word line.

9. The semiconductor apparatus of claim 7, wherein the unit cell includes:
a first transistor coupled between the second signal line and a data storage element;
a second transistor coupled between the first signal line and the data storage element; and
a switching circuit configured to, in response to a mode selection signal, switch the operation mode of the memory core between the first mode and the second mode, the first mode controlling the first transistor according to the level of the first signal line and turning off the second transistor and the second mode controlling the second transistor according to the level of the second signal line and turning off the first transistor.

10. The semiconductor apparatus of claim 9, wherein the switching circuit includes:
a first switch including a first terminal that is coupled to a gate terminal of the first transistor, a second terminal that is coupled to the first signal line, and a third terminal that is a ground terminal; and
a second switch including a first terminal that is coupled to a gate terminal of the second transistor, a second terminal that is coupled to the second signal line, and a third terminal that is coupled to the ground terminal.

11. The semiconductor apparatus of claim 9, wherein the memory core further includes:
a word line driver; and
a bit line sense amplifier,
wherein, in the first mode, the switching circuit is configured to couple the first signal line to the word line driver and configured to couple the second signal line to the bit line sense amplifier, and
wherein, in the second mode, the switching circuit is configured to couple the first signal line to the bit line sense amplifier and configured to couple the second signal line to the word line driver.

12. The semiconductor apparatus of claim 7, wherein, in response to a transposed matrix calculation control signal, the data I/O circuit includes a register coupled to a global I/O line and is configured to perform an operation for storing data of the global I/O line and an operation for transmitting data stored therein to the global I/O line.

13. The semiconductor apparatus of claim 12, wherein the data I/O circuit includes:
a read path configured to transmit data transmitted through the global I/O line to the data I/O pad circuit; and
a write path configured to transmit data input through the I/O pad circuit to the global I/O line.

14. A memory core comprising:
a word line and a bit line arranged in a matrix form; a a first transistor coupled between the bit line and a data storage element;
a second transistor coupled between the word line and the data storage element; and
a switching circuit configured to:
control the first transistor according to a level of the word line and turn off the second transistor when a mode selection signal has a level defining an operation mode of the memory core as a first mode and
control the second transistor according to a level of the bit line and turn off the first transistor when the mode selection signal has a level defining the operation mode of the memory core as a second mode.

15. The memory core of claim 14, wherein the switching circuit includes:
a first switch including a first terminal that is coupled to a gate terminal of the first transistor, a second terminal that is coupled to the word line, and a third terminal that is a ground terminal; and
a second switch including a first terminal that is coupled to a gate terminal of the second transistor, a second terminal that is coupled to the bit line, and a third terminal that is coupled to the ground terminal.

16. The memory core of claim 14, wherein the memory core further includes:
a word line driver; and
a bit line sense amplifier,
wherein, in the first mode, the switching circuit is configured to couple the word line to the word line driver and configured to couple the bit line to the bit line sense amplifier, and
wherein, in the second mode, the switching circuit is configured to couple the word line to the bit line sense amplifier and configured to couple the bit line to the word line driver.
